(19) United States
(12) Patent Application Publication
(10) Pub. No.: US 2018/0287024 A1
(43) Pub. Date: Oct. 4, 2018

(54) SEMICONDUCTOR LIGHT-EMITTING MODULE AND SEMICONDUCTOR LED CHIP THEREOF

(71) Applicant: HARVATEK CORPORATION, Hsinchu City (TW)

(72) Inventors: ZHI-TING YE, MIAOLI COUNTY (TW); SHYI-MING PAN, MIAOLI COUNTY (TW)

(21) Appl. No.: 15/637,598

(22) Filed: Jun. 29, 2017

(30) Foreign Application Priority Data
Mar. 29, 2017 (TW) 106110521

(51) Int. Cl. H01L 33/60; H01L 33/32

(52) U.S. Cl. CPC H01L 33/60; H01L 33/32

(57) ABSTRACT

The present invention provides a semiconductor light-emitting module and a semiconductor LED chip thereof. The semiconductor LED chip includes a semiconductor light-emitting structure, a light-guiding structure layer, and a light-reflecting structure layer. The semiconductor light-emitting structure includes a light-emitting layer for generating a projection light source. The light-guiding structure layer is connected to the semiconductor light-emitting structure. The light-reflecting structure layer is connected to the light-guiding structure layer. The projection light source generated by the light-emitting layer is projected into the light-guiding structure layer and onto the light-reflecting structure layer. The projection light source is guided and reflected by matching the light-guiding structure layer and the light-reflecting structure layer to form a wide-angle light source that is projected outwardly from an outer surface of the light-guiding structure layer.

### FIELD OF THE INVENTION

The present disclosure relates to a light-emitting module and a LED chip thereof, and more particularly to a semiconductor light-emitting module and a semiconductor LED chip thereof.

### BACKGROUND OF THE INVENTION

LEDs are now widely used as illuminators, indicators, or displays in many kinds of electronic products or industrial applications. One of the advantages of LEDs is that they consume much less electricity, or energy, as comparing with other traditional lighting devices. This is because the LEDs are known as solid state devices that generate light through a luminescence process. Thus, the light generated by LEDs is referred to “cold light”. In addition, another advantage of LEDs is its small size. However, the LED chip without any package body cannot provide a wide-angle light source or a wide illumination range.

### SUMMARY OF THE INVENTION

One aspect of the present disclosure relates to a semiconductor light-emitting module and a semiconductor LED chip thereof.

One of the embodiments of the present disclosure provides a semiconductor LED chip, comprising a semiconductor light-emitting structure, a light-guiding structure layer, and a light-reflecting structure layer. The semiconductor light-emitting structure includes a plurality of semiconductor material layers stacked on top of one another, and four of the semiconductor material layers respectively are a base layer, an n-type conductive layer, a light-emitting layer, and a p-type conductive layer. The light-guiding structure layer is connected to the base layer. The light-reflecting structure layer is connected to the light-guiding structure layer. The light-emitting layer is connected between the n-type conductive layer and the p-type conductive layer for generating a projection light source, and the light-guiding structure layer is connected between the base layer and the light-reflecting structure for receiving the projection light source. The projection light source generated by the light-emitting layer is projected into the light-guiding structure layer and onto the light-reflecting structure layer, and the projection light source is guided and reflected by matching the light-guiding structure layer and the light-reflecting structure layer to form a wide-angle light source that is projected outwardly from an outer surface of the light-guiding structure layer.

Another one of the embodiments of the present disclosure provides a semiconductor light-emitting module, comprising a circuit substrate and a semiconductor LED chip. The semiconductor LED chip is disposed on the circuit substrate, and the semiconductor LED chip includes a semiconductor light-emitting structure, a light-guiding structure layer, and a light-reflecting structure layer. The semiconductor light-emitting structure includes a plurality of semiconductor material layers stacked on top of one another, and four of the semiconductor material layers respectively are a base layer, an n-type conductive layer, a light-emitting layer, and a p-type conductive layer. The light-guiding structure layer is connected to the base layer. The light-reflecting structure layer is connected to the light-guiding structure layer. The n-type conductive layer has a first chip pad disposed on an outer side thereof, and the first chip pad of the n-type conductive layer is electrically connected to a first substrate pad of the circuit substrate through a first conductive unit. The p-type conductive layer has a second chip pad disposed on an outer side thereof, and the second chip pad of the p-type conductive layer is electrically connected to a second substrate pad of the circuit substrate through a second conductive unit. The light-emitting layer is connected between the n-type conductive layer and the p-type conductive layer for generating a projection light source, and the light-guiding structure layer is connected between the base layer and the light-reflecting structure for receiving the projection light source. The projection light source generated by the light-emitting layer is projected into the light-guiding structure layer and onto the light-reflecting structure layer, and the projection light source is guided and reflected by matching the light-guiding structure layer and the light-reflecting structure layer to form a wide-angle light source that is projected outwardly from an outer surface of the light-guiding structure layer.

Yet another one of the embodiments of the present disclosure provides a semiconductor LED chip, comprising a semiconductor light-emitting structure, a light-guiding structure layer, and a light-reflecting structure layer. The semiconductor light-emitting structure includes a light-emitting layer for generating a projection light source. The light-guiding structure layer is connected to the semiconductor light-emitting structure. The light-reflecting structure layer is connected to the light-guiding structure layer. The projection light source generated by the light-emitting layer is projected into the light-guiding structure layer and onto the light-reflecting structure layer, and the projection light source is guided and reflected by matching the light-guiding structure layer and the light-reflecting structure layer to form a wide-angle light source that is projected outwardly from an outer surface of the light-guiding structure layer.

Therefore, the projection light source is guided and reflected by matching the light-guiding structure layer and the light-reflecting structure layer to form a wide-angle light source that is projected outwardly from an outer surface of the light-guiding structure layer by matching the features of “the light-guiding structure layer being connected to the semiconductor light-emitting structure, and the light-reflecting structure layer being connected to the light-guiding structure layer” and “the projection light source generated by the light-emitting layer being projected into the light-guiding structure layer and onto the light-reflecting structure layer”.

To further understand the techniques, means and effects of the present disclosure, the following detailed descriptions and appended drawings are hereby referred to, such that, and through which, the purposes, features and aspects of the present disclosure can be thoroughly and concretely appreciated. However, the appended drawings are provided solely for reference and illustration, without any intention to limit the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 shows a schematic view of the semiconductor LED chip according to the first embodiment of the present disclosure;

FIG. 2 shows a schematic view of the semiconductor light-emitting module according to the second embodiment of the present disclosure;

FIG. 3 shows a schematic view of the semiconductor LED chip according to the third embodiment of the present disclosure;

FIG. 4 shows a schematic view of the semiconductor light-emitting module according to the fourth embodiment of the present disclosure;

FIG. 5 shows a schematic view of the semiconductor LED chip according to the fifth embodiment of the present disclosure; and

FIG. 6 shows a schematic view of the semiconductor light-emitting module according to the sixth embodiment of the present disclosure.

### DETAILED DESCRIPTION OF THE PREFERRED EMBODIMENTS

Embodiments of a semiconductor light-emitting module and a semiconductor LED chip thereof according to the present disclosure are described herein. Other advantages and objectives of the present disclosure can be easily understood by one skilled in the art from the disclosure. The present disclosure can be applied in different embodiments. Various modifications and variations can be made to various details in the description for different applications without departing from the scope of the present disclosure. The drawings of the present disclosure are provided only for simple illustrations, but are not drawn to scale and do not reflect the actual relative dimensions. The following embodiments are provided to describe in detail the concept of the present disclosure, and are not intended to limit the scope thereof in any way.

### First Embodiment

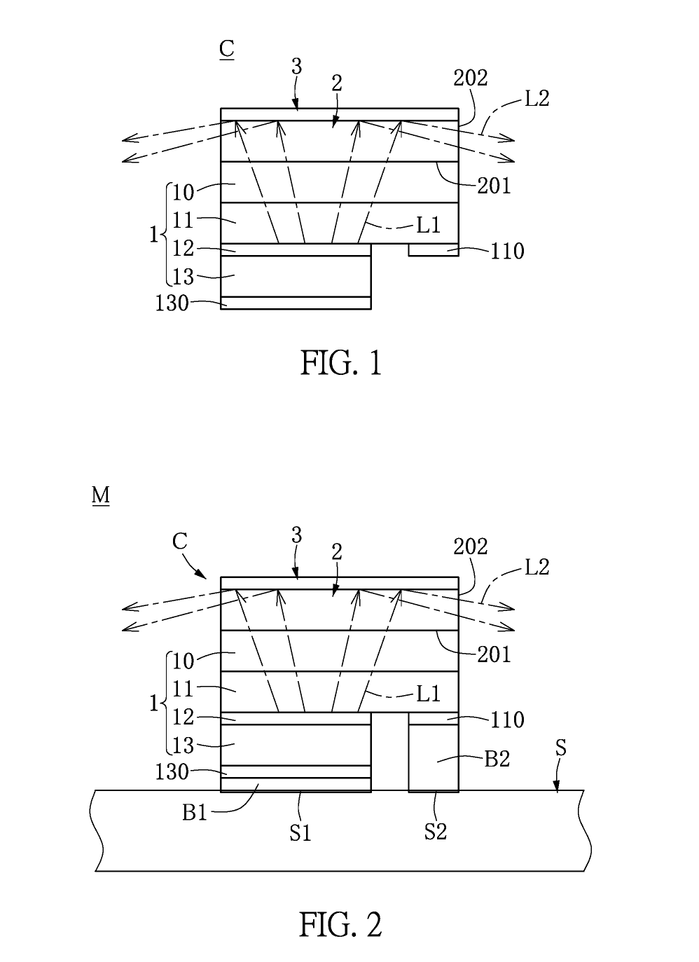

Referring to FIG. 1, the first embodiment of the present disclosure provides a semiconductor LED chip C, comprising a semiconductor light-emitting structure 1, a light-guiding structure layer 2, and a light-reflecting structure layer 3.

First, the semiconductor light-emitting structure 1 includes a plurality of semiconductor material layers stacked on top of one another. More particularly, four of the semiconductor material layers respectively are a base layer 10, an n-type conductive layer 11, a light-emitting layer 12, and a p-type conductive layer 13, and the light-emitting layer 12 is connected between the n-type conductive layer 11 and the p-type conductive layer 13 for generating a projection light source L1. In addition, the n-type conductive layer 11 has a first chip pad 110 disposed on an outer side thereof, and the p-type conductive layer 13 has a second chip pad 130 disposed on an outer side thereof.

For example, the base layer 10, the n-type conductive layer 11, the light-emitting layer 12, and the p-type conductive layer 13 are stacked on top of one another. In addition, the base layer 10 may be a sapphire material layer, the n-type conductive layer 11 may be an n-GaN material layer, the light-emitting layer 12 may be an MQW (Multiple Quantum Well) structure layer, and the p-type conductive layer 13 may be a p-GaN material layer. However, it is merely an example and is not meant to limit the scope of the present disclosure.

Moreover, the light-guiding structure layer 2 is connected to the base layer 10, and the light-reflecting structure layer 3 is connected to the light-guiding structure layer 2. More particularly, the light-guiding structure layer 2 is connected to the base layer 10 of the semiconductor light-emitting structure 1, so that the baser layer 10 is closer to the light-guiding structure layer 2 than the n-type conductive layer 11 is. In addition, the light-guiding structure layer 2 is connected between the base layer 10 and the light-reflecting structure 3 for receiving the projection light source L1. Therefore, the projection light source L1 generated by the light-emitting layer 12 is projected into the light-guiding structure layer 2 and onto the light-reflecting structure layer 3, and the projection light source L1 is guided and reflected by matching the light-guiding structure layer 2 and the light-reflecting structure layer 3 to form a wide-angle light source L2 that is projected outwardly from an outer surface of the light-guiding structure layer 2.

More particularly, the light-guiding structure layer 2 has a light input surface 201 and a surrounding light output surface 202 surroundingly connected with the light input surface 201. In addition, the light input surface 201 is connected to the base layer 10, and the surrounding light-output surface 202 is surroundingly connected between the base layer 10 and the light-reflecting structure layer 3. Therefore, the projection light source L1 generated by the light-emitting layer 12 is projected into the light-guiding structure layer 2 through the light input surface 201 (i.e., the projection light source L1 can pass through the light input surface 201 and then enter the light-guiding structure layer 2), and the projection light source L1 inside the light-guiding structure layer 2 is projected out of the light-guiding structure layer 2 through the surrounding light output surface 202 (i.e., the projection light source L1 can pass through the surrounding light output surface 202 and then leave the light-guiding structure layer 2) to form the wide-angle light source L2.

It should be noted that the thickness of the light-guiding structure layer 2 is substantially between 0.4 mm and 0.8 mm. The light output efficiency of the semiconductor LED chip C with the light-guiding structure layer 2 is larger about 10%-20% than that of the semiconductor LED chip C without the light-guiding structure layer 2. That is to say, the light-guiding structure layer 2 is connected between the light-reflecting structure layer 3 and the base layer 10 so as to separate the light-reflecting structure layer 3 from the base layer 10, so that the light output efficiency of the semiconductor LED chip C with the light-guiding structure layer 2 can be increased about 10%-20% that is more than the light output efficiency of the semiconductor LED chip C without the light-guiding structure layer 2.

### Second Embodiment

Referring to FIG. 2, the second embodiment of the present disclosure provides a semiconductor light-emitting module M. The semiconductor light-emitting module M comprises a circuit substrate S and a semiconductor LED chip C disposed on the circuit substrate S, and the semiconductor LED chip C includes a semiconductor light-emitting structure 1, a light-guiding structure layer 2, and a light-reflecting structure layer 3. Comparing FIG. 2 with FIG. 1, the difference between the second embodiment and the first embodiment is as follows: in the second embodiment, the semiconductor LED chip C is disposed on the circuit substrate S and electrically connected to the circuit substrate S by flip-chip bump bonding.

More particularly, the n-type conductive layer 11 has a first chip pad 110 disposed on an outer side thereof, and the first chip pad 110 of the n-type conductive layer 11 is electrically connected to a first substrate pad S1 of the circuit substrate S through a first conductive unit B1 (such as solder ball or solder paste). In addition, the p-type conductive layer 13 has a second chip pad 130 disposed on an outer side thereof, and the second chip pad 130 of the p-type conductive layer 13 is electrically connected to a second substrate pad S2 of the circuit substrate S through a second conductive unit B2 (such as solder ball or solder paste). That is to say, the first chip pad 110 and the second chip pad 130 of the semiconductor LED chip C are respectively electrically connected to the first substrate pad S1 and the second substrate pad S2 of the circuit substrate S by respectively using the first conductive unit B1 and the second conductive unit B2, so that the semiconductor LED chip C can be electrically connected to the circuit substrate S.

### Third Embodiment

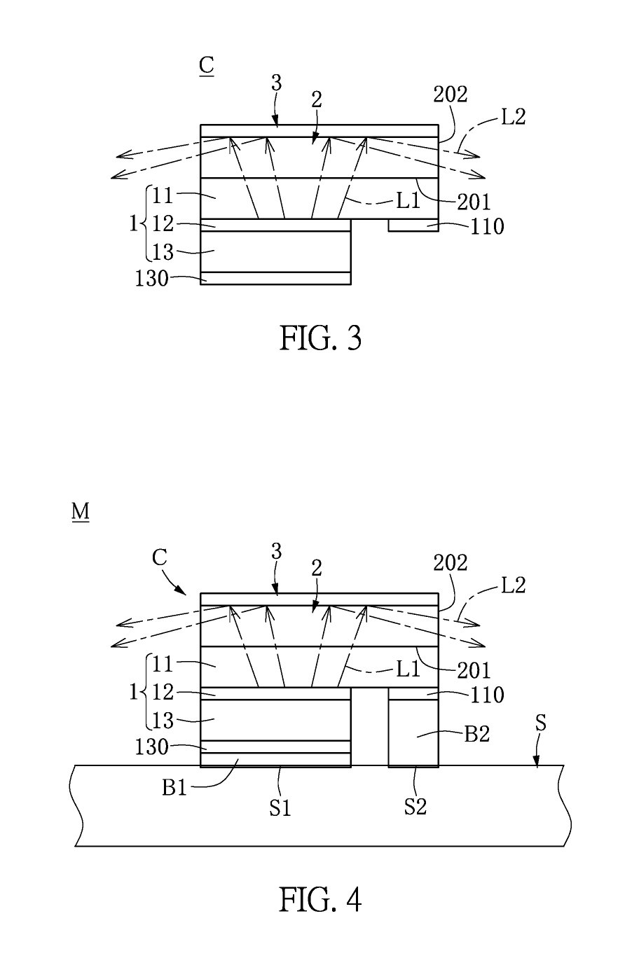

Referring to FIG. 3, the third embodiment of the present disclosure provides a semiconductor LED chip C, comprising a semiconductor light-emitting structure 1, a light-guiding structure layer 2, and a light-reflecting structure layer 3. The semiconductor light-emitting structure 1 includes a light-emitting layer 12 for generating a projection light source L1. The light-guiding structure layer 2 is connected to the semiconductor light-emitting structure 1, and the light-reflecting structure layer 3 is connected to the light-guiding structure layer 2. Therefore, the projection light source L1 generated by the light-emitting layer 12 is projected into the light-guiding structure layer 2 and onto the light-reflecting structure layer 3, and the projection light source L1 is guided and reflected by matching the light-guiding structure layer 2 and the light-reflecting structure layer 3 to form a wide-angle light source L2 that is projected outwardly from an outer surface of the light-guiding structure layer 2.

More particularly, the semiconductor light-emitting structure 1 includes an n-type conductive layer 11 and a p-type conductive layer 13. In addition, the light-guiding structure layer 2 is connected to the n-type conductive layer 11 of the semiconductor light-emitting structure 1, so that the n-type conductive layer 11 is closer to the light-guiding structure layer 2 than the p-type conductive layer 13 is.

More particularly, the light-guiding structure layer 2 has a light input surface 201 and a surrounding light output surface 202 surroundingly connected with the light input surface 201. In addition, the light input surface 201 is connected to the n-type conductive layer 11, and the surrounding light-output surface 202 is surroundingly connected between the n-type conductive layer 11 and the light-reflecting structure layer 3. Therefore, the projection light source L1 generated by the light-emitting layer 12 is projected into the light-guiding structure layer 2 through the light input surface 201, and the projection light source L1 inside the light-guiding structure layer 2 is projected out of the light-guiding structure layer 2 through the surrounding light output surface 202 to form the wide-angle light source L2.

It should be noted that the thickness of the light-guiding structure layer 2 is substantially between 0.4 mm and 0.8 mm. The light output efficiency of the semiconductor LED chip C with the light-guiding structure layer 2 is larger about 10%-20% than that of the semiconductor LED chip C without the light-guiding structure layer 2. That is to say, the light-guiding structure layer 2 is connected between the light-reflecting structure layer 3 and the base layer 10 so as to separate the light-reflecting structure layer 3 from the base layer 10, so that the light output efficiency of the semiconductor LED chip C with the light-guiding structure layer 2 can be increased about 10%-20% that is more than the light output efficiency of the semiconductor LED chip C without the light-guiding structure layer 2.

### Fourth Embodiment

Referring to FIG. 4, the fourth embodiment of the present disclosure provides a semiconductor light-emitting module M. The semiconductor light-emitting module M comprises a circuit substrate S and a semiconductor LED chip C disposed on the circuit substrate S, and the semiconductor LED chip C includes a semiconductor light-emitting structure 1, a light-guiding structure layer 2, and a light-reflecting structure layer 3. Comparing FIG. 4 with FIG. 3, the difference between the fourth embodiment and the third embodiment is as follows: in the fourth embodiment, the semiconductor LED chip C is disposed on the circuit substrate S and electrically connected to the circuit substrate S by flip-chip bump bonding.

More particularly, the n-type conductive layer 11 has a first chip pad 110 disposed on an outer side thereof, and the first chip pad 110 of the n-type conductive layer 11 is electrically connected to a first substrate pad S1 of the circuit substrate S through a first conductive unit B1 (such as solder ball or solder paste). In addition, the p-type conductive layer 13 has a second chip pad 130 disposed on an outer side thereof, and the second chip pad 130 of the p-type conductive layer 13 is electrically connected to a second substrate pad S2 of the circuit substrate S through a second conductive unit B2 (such as solder ball or solder paste). That is to say, the first chip pad 110 and the second chip pad 130 of the semiconductor LED chip C are respectively electrically connected to the first substrate pad S1 and the second substrate pad S2 of the circuit substrate S by respectively using the first conductive unit B1 and the second conductive unit B2, so that the semiconductor LED chip C can be electrically connected to the circuit substrate S.

### Fifth Embodiment

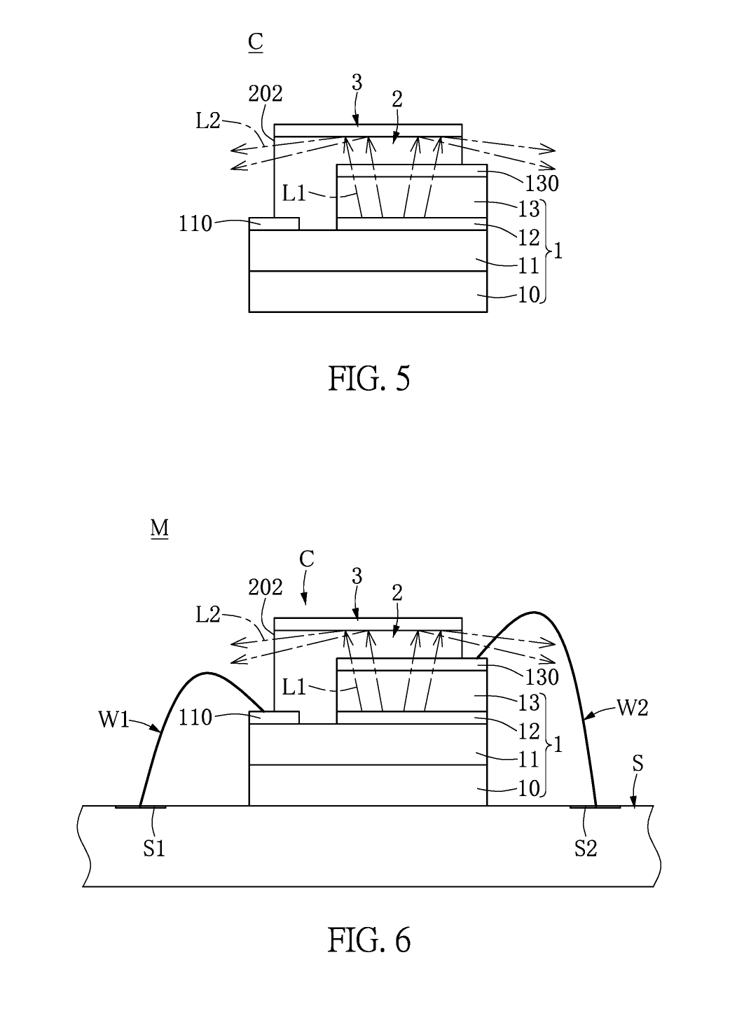

Referring to FIG. 5, the fifth embodiment of the present disclosure provides a semiconductor LED chip C, comprising a semiconductor light-emitting structure 1, a light-guiding structure layer 2, and a light-reflecting structure layer 3. The semiconductor light-emitting structure 1 includes a light-emitting layer 12 for generating a projection light source L1. The light-guiding structure layer 2 is connected to the semiconductor light-emitting structure 1, and the light-reflecting structure layer 3 is connected to the light-guiding structure layer 2. Therefore, the projection light source L1 generated by the light-emitting layer 12 is projected into the light-guiding structure layer 2 and onto the light-reflecting structure layer 3, and the projection light source L1 is guided and reflected by matching the light-guiding structure layer 2 and the light-reflecting structure layer 3 to form a wide-angle light source L2 that is projected outwardly from an outer surface of the light-guiding structure layer 2.

More particularly, the semiconductor light-emitting structure 1 includes a base layer 10, an n-type conductive layer 11, and a p-type conductive layer 13. In addition, the light-guiding structure layer 2 is connected to the p-type conductive layer 13 of the semiconductor light-emitting structure 1, so that the p-type conductive layer 13 is closer to the light-guiding structure layer 2 than the light-emitting layer 12 is.

More particularly, the light-guiding structure layer 2 has a light input surface (not shown) and a surrounding light output surface 202 surroundingly connected with the light input surface. In addition, the light input surface is connected to the p-type conductive layer 13, and the surrounding light-output surface 202 is surroundingly connected between the p-type conductive layer 13 and the light-reflecting structure layer 3. Therefore, the projection light source L1 generated by the light-emitting layer 12 is projected into the light-guiding structure layer 2 through the light input surface 201, and the projection light source L1 inside the light-guiding structure layer 2 is projected out of the light-guiding structure layer 2 through the surrounding light output surface 202 to form the wide-angle light source L2.

It should be noted that the thickness of the light-guiding structure layer 2 is substantially between 0.4 mm and 0.8 mm. The light output efficiency of the semiconductor LED chip C with the light-guiding structure layer 2 is larger about 10%-20% than that of the semiconductor LED chip C without the light-guiding structure layer 2. That is to say, the light-guiding structure layer 2 is connected between the light-reflecting structure layer 3 and the base layer 10 so as to separate the light-reflecting structure layer 3 from the base layer 10, so that the light output efficiency of the semiconductor LED chip C with the light-guiding structure layer 2 can be increased about 10%-20% that is more than the light output efficiency of the semiconductor LED chip C without the light-guiding structure layer 2.

### Sixth Embodiment

Referring to FIG. 6, the sixth embodiment of the present disclosure provides a semiconductor light-emitting module M. The semiconductor light-emitting module M comprises a circuit substrate S and a semiconductor LED chip C disposed on the circuit substrate S, and the semiconductor LED chip C includes a semiconductor light-emitting structure 1, a light-guiding structure layer 2, and a light-reflecting structure layer 3. Comparing FIG. 6 with FIG. 5, the difference between the sixth embodiment and the fifth embodiment is as follows: in the sixth embodiment, the semiconductor LED chip C is disposed on the circuit substrate S and electrically connected to the circuit substrate S by flip-chip bump bonding.

More particularly, the n-type conductive layer 11 has a first chip pad 110 disposed on an outer side thereof, and the first chip pad 110 of the n-type conductive layer 11 is electrically connected to a first substrate pad S1 of the circuit substrate S through a first conductive unit W1 (such as conductive wire). In addition, the p-type conductive layer 13 has a second chip pad 130 disposed on an outer side thereof, and the second chip pad 130 of the p-type conductive layer 13 is electrically connected to a second substrate pad S2 of the circuit substrate S through a second conductive unit W2 (such as conductive wire). That is to say, the first chip pad 110 and the second chip pad 130 of the semiconductor LED chip C are respectively electrically connected to the first substrate pad S1 and the second substrate pad S2 of the circuit substrate S by respectively using the first conductive unit W1 and the second conductive unit W2, so that the semiconductor LED chip C can be electrically connected to the circuit substrate S.

Therefore, the projection light source L1 is guided and reflected by matching the light-guiding structure layer 2 and the light-reflecting structure layer 3 to form a wide-angle light source L2 that is projected outwardly from an outer surface of the light-guiding structure layer 2 by matching the features of “the light-guiding structure layer 2 being connected to the semiconductor light-emitting structure 1, and the light-reflecting structure layer 2 being connected to the light-guiding structure layer 3” and “the projection light source L1 generated by the light-emitting layer 12 being projected into the light-guiding structure layer 2 and onto the light-reflecting structure layer 3”.

The aforementioned descriptions merely represent the preferred embodiments of the present disclosure, without any intention to limit the scope of the present disclosure which is fully described only within the following claims. Various equivalent changes, alterations or modifications based on the claims of the present disclosure are all, consequently, viewed as being embraced by the scope of the present disclosure.

1. A semiconductor LED chip, comprising:
a semiconductor light-emitting structure including a base layer, an n-type conductive layer, a light-emitting layer, and a p-type conductive layer stacked on top of one another;
a light-guiding structure layer connected to the p-type conductive layer, wherein the p-type conductive layer is closer to the light-guiding structure layer than the light-emitting layer is; and
a light-reflecting structure layer connected to the light-guiding structure layer;
wherein the light-guiding structure layer has a light input surface and a surrounding light output surface surroundingly connected with the light input surface, the light input surface is connected to the p-type conductive layer, and the surrounding light-output surface is surroundingly connected between the p-type conductive layer and the light-reflecting structure layer;
wherein a projection light source generated by the light-emitting layer is projected into the light-guiding structure layer and onto the light-reflecting structure layer, and the projection light source is guided and reflected by matching the light-guiding structure layer and the light-reflecting structure layer to form a wide-angle light source that is projected outwardly from an outer surface of the light-guiding structure layer.

2. The semiconductor LED chip of claim 1, wherein and the thickness of the light-guiding structure layer is substantially between 0.4 mm and 0.8 mm, wherein the base layer is a sapphire material layer, the n-type conductive layer is an n-GaN material layer, and the p-type conductive layer is a p-GaN material layer.

3. (canceled)

4. A semiconductor light-emitting module, comprising:
a circuit substrate; and
a semiconductor LED chip disposed on the circuit substrate, wherein the semiconductor LED chip includes:
a semiconductor light-emitting structure including a base layer, an n-type conductive layer, a light-emitting layer, and a p-type conductive layer stacked on top of one another;
a light-guiding structure layer connected to the p-type conductive layer, wherein the p-type conductive layer is closer to the light-guiding structure layer than the light-emitting layer is; and
a light-reflecting structure layer connected to the light-guiding structure layer;
wherein the n-type conductive layer has a first chip pad disposed on an outer side thereof, and the first chip pad of the n-type conductive layer is electrically connected to a first substrate pad of the circuit substrate through a first conductive unit;
wherein the p-type conductive layer has a second chip pad disposed on an outer side thereof, and the second chip pad of the p-type conductive layer is electrically connected to a second substrate pad of the circuit substrate through a second conductive unit;
wherein the light-guiding structure layer has a light input surface and a surrounding light output surface surroundingly connected with the light input surface, the light input surface is connected to the p-type conductive layer, and the surrounding light-output surface is surroundingly connected between the p-type conductive layer and the light-reflecting structure layer;
wherein a projection light source generated by the light-emitting layer is projected into the light-guiding structure layer and onto the light-reflecting structure layer, and the projection light source is guided and reflected by matching the light-guiding structure layer and the light-reflecting structure layer to form a wide-angle light source that is projected outwardly from an outer surface of the light-guiding structure layer.

5. The semiconductor light-emitting module of claim 4, wherein the thickness of the light-guiding structure layer is substantially between 0.4 mm and 0.8 mm, wherein the base layer is a sapphire material layer, the n-type conductive layer is an n-GaN material layer, and the p-type conductive layer is a p-GaN material layer.

6-10. (canceled)
